(19) United States
(12) Patent Application Publication
(10) Pub. No.: US 2009/0272841 A1
(43) Pub. Date: Nov. 5, 2009

(54) Albedo-derived airship power system

(76) Inventors: Steven L. Sinsabaugh, Uniontown, OH (US); Thomas L. Marimon, Silver Lake, OH (US)

Correspondence Address: RENNER KENNER GREIVE BOBAK TAYLOR & WEBER, FIRST NATIONAL TOWER FOURTH FLOOR, 106 S. MAIN STREET, AKRON, OH, 44308, US

(21) Appl. No.: 12/151,263

(22) Filed: May 5, 2008

(51) Int. Cl. B64B 1/00; B64D 41/00; H01L 31/042

(52) U.S. Cl. 244/30; 244/58; 136/244; 136/291

(57) ABSTRACT

A power generation system for an airship includes a solar array and an Earth array for converting solar radiation and albedo radiation, respectively, into electrical energy. The airship also carries a power distribution controller to receive the electrical energy for transfer to a power storage device and/or electrical components carried by the airship. The airship may also receive a man-made radiation source purposefully directed at the Earth array.

### TECHNICAL FIELD

Generally, the present invention relates to a power generation system for an airship. Specifically, the present invention relates to a power generation system for an airship that harnesses the solar energy reflected by the Earth and its atmosphere. Particularly, the present is directed to a power generation system for an airship that improves the power generation capabilities of an airship while at the same time improving the airship's physical properties.

### BACKGROUND

Solar energy has long been recognized as a desirable power source to provide either primary or supplementary power to airships, aerostats, and other lighter-than-air vehicles and platforms. The benefits of solar power have been particularly recognized for the subset of those vehicles and platforms that fly at high altitudes and/or for long durations, where it is impractical to carry sufficient fuel, such as hydrogen, hydrocarbons, or other fuels to provide power for weeks, months, or years. The ability to capture solar power each day (and, if desired, store excess power in batteries, fuel cells or other energy storage systems for later use) is a key enabling technology for many fields, including stratospheric airships.

The conventional approach for converting the sun's radiant energy into useful energy for stratospheric airships is with solar cells. A solar cell, which may also be called a photovoltaic cell, is a device that converts solar electromagnetic energy into electricity by the photovoltaic effect. According to the theories behind the photovoltaic effect, and as is well understood in the art, electromagnetic energy from the sun, or sunlight, is absorbed by semiconducting materials of the solar cell. The energy is absorbed by electrons in the semiconducting material, and if the amount of energy (a function of the frequency of the incident radiation) exceeds a threshold value (bandgap), electrons are released from the atoms of the semiconducting material, and the flow of these electrons generates electrical energy, which can then be transformed into electrical power.

Solar cells convert only a fraction of the incident sunlight (insolation) into electrical energy. Currently, solar cells are capable of converting less than 50% of the electromagnetic energy in sunlight into electrical energy, with much of the remaining energy being converted into thermal energy, or heat. The amount of incident solar energy ranges from about 1000 watts per square meter (W/m²) at sea level to over 1350 W/m² at stratospheric altitudes. Given the energy conversion efficiencies of present day, or even projected, solar cells, those experienced in the art will appreciate that a large surface area of solar cells would be needed to provide electrical power to lighter-than-air vehicles and any electrical equipment such vehicles may carry.

Conventional airship and aerostat designs typically have a main hull designed to be aerodynamic and generally symmetric about the longitudinal axis. Alternate approaches are symmetrical around a central vertical axis. It is generally known in the art to incorporate solar cells into the upper, or sun-facing, half of the hull. Design emphasis has been placed on optimizing the placement of the solar cells to maximize exposure to direct sunlight (and hence, to maximize generation of electrical power), while minimizing weight, drag, and detrimental thermal effects. However, certain practical realities associated with prior art designs have created challenges that limit the power-generation capabilities of a solar cell equipped airship.

One of these challenges includes shadowing and effects related to the curvature of the collection of solar cells (solar array) installed on the airship hull. A solar array laid on the curved surface of an airship will not be flat. The curvature of the hull impacts solar cell performance in those portions of the solar array with large sun angles (defined as the angle between a normal to the solar cell and the path to the sun), whereby large sun angles reduce the effective performance of a solar cell. For sun angles greater than 90°, a solar cell is in the shade and no direct sunlight reaches it. Because a hull-mounted solar array has a variety of local sun angles due to hull curvature, the solar array never achieves its maximum theoretical performance. Thus, designers are presently required to increase the size of the solar array to account for this sun-angle ineffectiveness.

Another challenge is the apparent motion of the sun. According to an Earth-based observer, the sun is in constant movement, crossing the sky from east to west. This motion results in continuously changing sun angles for each solar cell of the solar array through the day, even if the airship or aerostat itself remains stationary. The sun position (both azimuth and elevation) depends not only on the time of day, but also the time of year and latitude. Thus, the portion of the solar array that is shadowed is continuously changing. This source of ineffectiveness also forces designers to compensate for the reduction in effective performance of the solar cells by increasing the size of the solar array.

An additional challenge is the variability in wind direction. Airships or aerostats that are attempting to hold a relative position tend to yaw until oriented into the wind. This movement compounds the complication of the motion of the sun, and thus further reduces the effective performance of the solar array.

Yet another challenge is operating a solar powered airship or aerostat in high latitudes during hemispheric winters. Those skilled in the art will appreciate that operation of a solar powered airship under those conditions is challenging due to the combination of very short days (reducing the amount of time solar power is available), very long nights (increasing the amount of solar power required to recharge batteries), and very low sun angles. This combination of factors makes operating a solar powered airship at high latitudes in hemispheric winters difficult at best.

Even another challenge is the thermal effects caused by the solar array. Because solar arrays are designed to maximize absorption of solar radiation, placing the solar array on top of the hull has a detrimental thermal effect. Again, a significant portion of the energy incident to a solar cell is converted to thermal energy. Those skilled in the art will appreciate that this thermal energy heats up the airship's lifting gas during the day, thereby causing the pressure to increase. As the gas cools during the night, the pressure decreases. This daily (diurnal) cycling increases the performance demands on the hull fabric, since the greater the pressure change, the more strength (and ultimately weight) is needed in the hull fabric. Conventional designs include hull fabric coatings that maximize reflection and minimize the transmissivity of solar radiation into the hull in order to minimize these diurnal lifting gas temperature changes. Thus, as the surface area of the hull taken up by the solar array increases, the surface area of the hull fabric having coatings that reflect solar radiation decreases.

Another challenge is the weight of the solar array. The solar array is located on the top of the airship and may be comprised of many distinct solar cells. These solar cells are interconnected by electrical circuitry, and the current generated by the solar array is connected and transferred to other parts of the airship by cabling means, all of these contributing to the weight of the airship. Because of the geometry of an airship, weight distributions on the top of the airship are less stable, and therefore less desirable, than weight distributions on the bottom.

It is known in some instances to use “blackbody” radiation as an energy source. Blackbody radiation is sometimes called outgoing longwave radiation (OLR) or long-wave infrared (LWIR). It is not reflected sunlight, but rather the radiation due to the Earth's temperature. This radiation is in a distinct separate spectral band being typically from 5 microns (μm) to 40 microns wavelength. OLR is continuous, day and night, and if utilized on a stratospheric airship would impinge at about 200 W/m². This radiation cannot be converted to useful electrical energy via conventional photovoltaic or photoelectrochemical means, since the photon energy is on the order of only 0.1 electron volts (eV), much lower than the bandgap of any conventional photovoltaic cells. Thermodynamically, energy harvesting in this spectrum is only possible if the receiver is cooled with respect to the source blackbody temperature. For example, the blackbody temperature of high cloud tops is on the order of −40° C. to −60° C. Under these conditions, the only way a receiver on the stratospheric airship can collect energy is if it is at a colder temperature, and then the theoretical efficiency (Carnot) is proportional to the temperature difference. In the related art of LWIR optical sensors, the conventional practice is to cool the sensors to cryogenic temperatures to enable even modest photo-to-electron conversion efficiency. The energy required for cooling a photovoltaic receiver for OLR energy collection, or mass of stored cryogenic coolant, is prohibitive for mass-sensitive airship systems. This same requirement for the energy source being at a higher temperature than the energy receiver also applies to both direct solar insolation and Earth albedo radiation conversion; in this case, the primary energy source is the sun, with a blackbody temperature of approximately 6000° C.

Thus, there exists a need in the art for an improved power generation system for an airship or aerostat, which enhances power generation and reduces the negative aspects of solar array use.

### SUMMARY OF THE INVENTION

In light of the foregoing, it is a first aspect of the present invention to provide an albedo-derived airship power system

Another aspect of the present invention is to provide an airship and power generation system comprising a hull having a top portion and a bottom portion, a solar array carried by the top portion, an Earth array carried by the bottom portion, wherein the solar array converts solar radiation into electrical energy and the Earth array converts albedo radiation into electrical energy, and a power distribution controller which receives electrical energy from the solar array and the Earth Array.

Still another aspect of the present invention is to provide a method for powering an airship comprising providing an airship having electronic devices and a hull with a top portion and a bottom portion, providing an Earth array on the bottom portion, connecting a power distribution controller to the Earth array electronic devices, connecting a power storage device to the power distribution controller, converting incident radiation impinging on the Earth array into electrical energy, receiving the electrical energy in the power distribution controller, and transferring electrical energy between the power distribution controller, the power storage device, and the electronic devices.

### BRIEF DESCRIPTION OF THE DRAWINGS

This and other features and advantages of the present invention will become better understood with regard to the following description, appended claims, and accompanying drawings wherein:

FIG. 1 is a schematic representation of the front elevational view of an airship built in accordance with an embodiment of the present invention in operational circumstances;

FIG. 2 is a perspective view of the airship incorporating the concepts of the present invention;

FIG. 3 is a schematic cross-sectional view of the airship;

FIG. 4 is a spectral plot showing the difference between solar radiation and outgoing longwave radiation; and

FIG. 5 is a plot showing the electrical power created over time by a solar array and Earth array.

### BEST MODE FOR CARRYING OUT THE INVENTION

While direct solar illumination of a solar cell is the strongest available natural source of sunlight, it is not the only source of electromagnetic, or radiant, energy. The radiant energy incident on an operational aerostat or airship also includes sunlight reflected by the Earth and the Earth's atmosphere. This reflected sunlight is commonly referred to as albedo radiation, or simply albedo. Albedo is defined as the ratio of reflected to incident electromagnetic radiation, and is a unitless measure indicative of a surface's reflectivity. Typical albedo values for various surfaces range from about 4% for charcoal to about 90% for freshly fallen snow. It is believed that the average Earth albedo is about 30%. Thus, an airship operating in Earth's stratosphere is illuminated by both direct solar and albedo radiation during daylight hours.

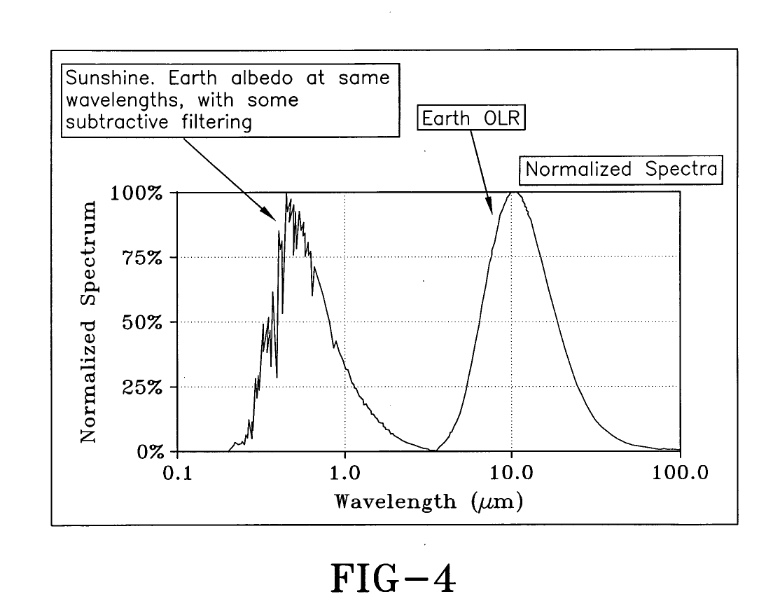

Direct solar radiation at the top of Earth's atmosphere primarily includes wavelengths between about 0.2 microns (μm) and 3.0 microns. As direct solar radiation travels through Earth's atmosphere, a portion of its energy is absorbed by various gases, particles, and solid objects, including the Earth's surface. The remainder of the energy is reflected, and this is referred to as albedo. Thus, albedo radiation is radiation having a spectral range similar to direct solar radiation but with differences between the two spectra relating to absorption of a portion of the direct solar radiation. Again, since albedo is the ratio of reflected to incident radiation, albedo radiation has only a fraction of the energy per unit area as direct solar radiation. This fraction is non-negligible, however, because average Earth albedo is about 30%, with localized regions reflecting various amounts of direct solar radiation. This albedo radiation can be converted to useful electrical energy via conventional photovoltaic or photoelectrochemical cells, or via thermal engines and potentially thermoelectric cells. And again, direct solar radiation and albedo radiation are different from Earth's blackbody radiation, or OLR radiation. Briefly referring to FIG. 4, it is apparent that sunlight, and therefore also albedo radiation, occupy a spectral range distinct from Earth blackbody radiation, or Earth OLR.

While the present invention is described in the context of a power generation system for an airship, one of skill in the art would appreciate the applicability of the invention to other vehicles or platforms, including aerostats and other lighter-than-air platforms, heavier-than-air platforms, or any other object having surfaces illuminated by albedo radiation.

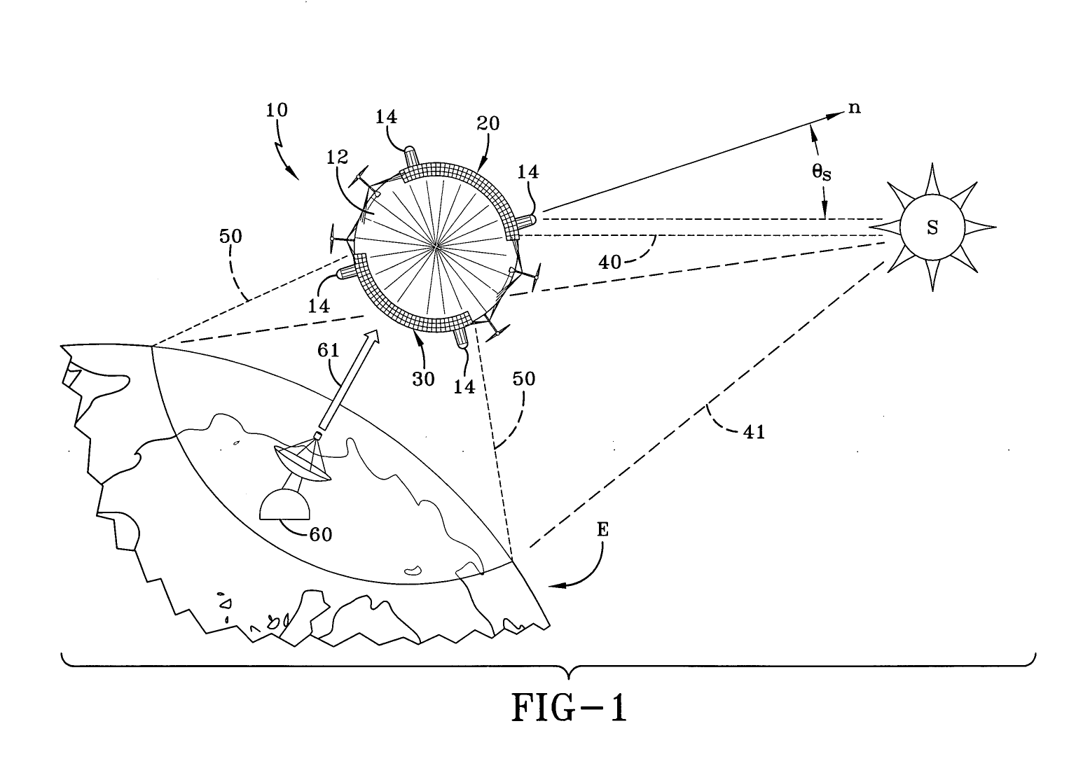

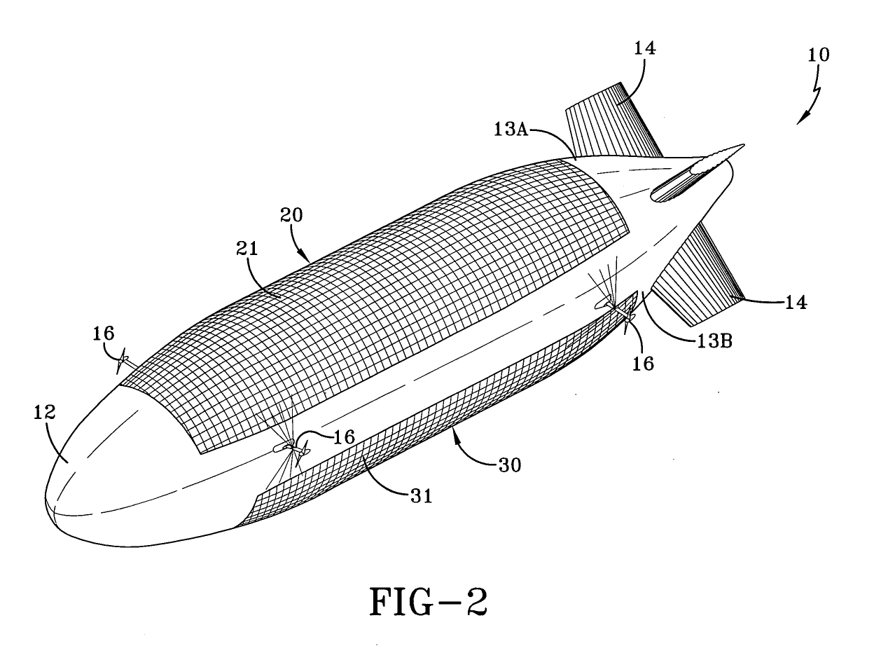

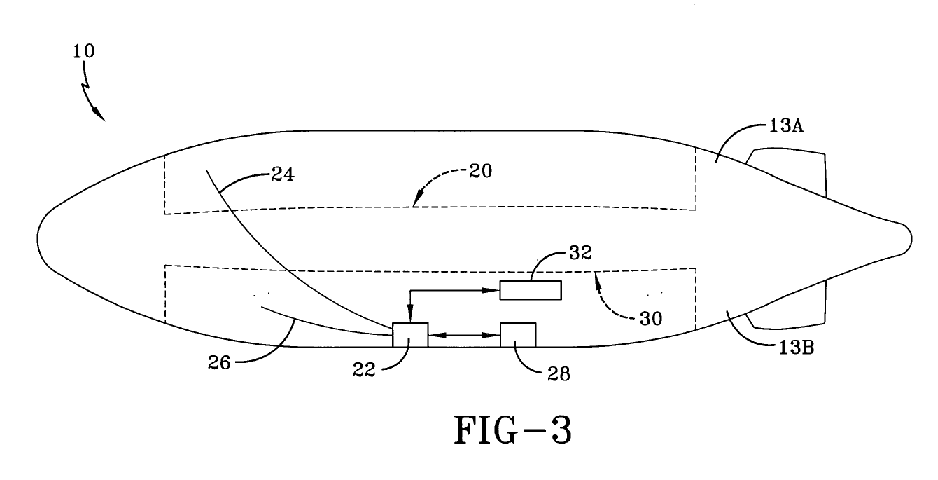

Referring now to the drawings and in particular to FIGS. 1-3, an airship having a power generation system constructed in accordance with an embodiment of the present invention is designated generally by the numeral 10. Airship 10 includes an exterior surface, or hull 12, which may generally be subdivided into a top portion 13A and a bottom portion 13B, and stabilizing fins or rudders 14. Hull 12 contains gas bags or ballonets (not shown) that contain a lifting gas, such as helium. Hull 12 also contains an air volume (not shown) that exists in a volume complementary to the gas bags of the hull 12. Hull 12 may be made of suitable materials well known in the art, including flexible and rigid materials. Hull 12 may also include coatings or other surface treatments for such purposes as maximizing reflection of incident radiation and minimizing the transmissivity of the incident radiation into the hull. Airship 10 also includes propellers 16 for controlling the movement of airship 10. Of course, other propulsion devices could be used in place of or in conjunction with the propellers.

A sun-facing top solar array 20 is affixed to the generally top portion 13A. Solar array 20 may be comprised of distinct solar cells 21 that are electrically connected to one another to form solar array 20. Solar array 20 produces electrical energy by the photovoltaic effect, and the electrical energy produced by solar array 20 is collected and delivered to power distribution controller 22 by electrically conductive wires 24.

An Earth-facing bottom Earth array 30 is affixed to the generally bottom portion 13B. Earth array 30 may also be comprised of distinct solar cells 31 that are electrically connected to one another to form Earth array 30. Earth array 30 produces electrical energy by the photovoltaic effect, and the electrical energy produced by Earth array 30 is collected and delivered to power distribution controller 22 by electrically conductive wires 26. It will be appreciated that wires 26 connecting Earth array 30 to the controller 22, which is usually maintained on the underside of the hull, are comparatively shorter than the wires 24. This could potentially save on the overall weight of the airship if sufficient electrical energy can be generated by Earth array 30 to allow for a reduction in the size or elimination of solar array 20, and could also improve the distribution of weight within the airship.

Solar array 20 and Earth array 30 may be made of any substance to affect the conversion of electromagnetic radiation into electrical energy, particularly by the photovoltaic effect. Solar array 20 and Earth array 30 may be made of similar solar cells, or solar array 20 and Earth array 30 may be designed to account for the spectral differences between direct solar radiation and albedo radiation, with the spectral difference at least partially influenced by atmospheric filtering and surface reflectivity.

Both direct solar radiation and albedo radiation include wavelengths between about 0.2 microns (μm) and 3.0 microns, and differences in the spectra relate to absorption of a portion of the direct solar radiation. Solar cells may be selected for the solar array 20 that are specifically tailored to the spectrum for direct solar radiation. And, solar cells may be selected for Earth array 30 that are specifically tailored to the spectrum for albedo radiation. Because the spectrum for albedo radiation depends on operational conditions, one of skill in the art would appreciate that different solar cells might be selected for Earth array 30 if airship 10 is operated over a largely snowy portion of the Earth than if over a largely forested portion of the Earth.

While solar array 20 and Earth array 30 are depicted as covering approximately the same surface area, one of skill in the art would appreciate that the relative size of each array may be adjusted for particular operational circumstances based on such factors as total electrical energy requirements, solar cell electrical conversion efficiency, electrical storage capability, magnitude of incident solar and albedo radiation, thermal effects, desired weight distribution, and the like.

Power distribution controller 22 facilitates transfer of electrical energy between the various components of the airship 10, including power producing components including solar array 20 and Earth array 30, power consuming components, including propeller 16 and the other electronic devices 32 of airship 10, and power storage components including power storage device 28. Power distribution controller 22 also provides the appropriate control signals for facilitating these transfers of electrical energy. Power storage device 28 facilitates the storage of electrical energy and may take the form of an electrochemical cell battery, a fuel cell, or the like. While power distribution controller 22 and power storage device 28 are depicted inside hull 12, it will be appreciated that power distribution controller 22 and power storage device 28 may be located in other areas of an airship, including outside the hull, or in a gondola or other payload compartment (not shown). Moreover, while wires 24 and 26 are depicted as single cables, they could take any form that allows for the transfer of electrical energy from solar array 20 and Earth array 30 to power distribution controller 22.

The schematic of FIG. 1 shows airship 10 in operational circumstances, with airship 10 flying at an altitude above Earth E. Both airship 10 and Earth E are illuminated by sunlight 40. Sunlight 40 is incident upon solar array 20 so that localized regions of solar array 20 are characterized by a sun angle Θₛ, where Θₛ is defined as the angle between the local normal n of the solar array 20 and the path to the sun S. As shown in FIG. 1, portions of solar array 20 may be characterized by high sun angles Θₛ, and other portions of solar array 20 may be in the shade. Sunlight 41 is incident upon Earth E, as well as its atmosphere (not shown), and a portion of this direct solar radiation is reflected from Earth E and its atmosphere, including clouds and anything else between Earth E and airship 10 as albedo radiation 50. Albedo radiation 50 illuminates a portion of airship 10, including Earth array 30. Depending on the relative position of the sun S, Earth array 30 may also be illuminated by direct sunlight 40. As FIG. 1 shows, Earth array 30 is generally fully illuminated by albedo radiation 50, despite the possibility that portions of solar array 20 may have high sun angles or areas in the shade because of the relative position of the sun S.

Also, man-made sources of electromagnetic radiation, such as visible and near-infrared laser beams (i.e., having wavelengths compatible with Earth array 30) could be used to supplement the collection of sunlight 40 and albedo radiation 50 by airship 10, without additional components or mass. As seen in FIG. 1, a terrestrial light source 60 creates light 61 that illuminates airship 10. Light 61 supplements the other radiation incident upon Earth array 30, including sunlight 40 and albedo radiation 50 and further contributes to the creation of electrical energy. By using man-made sources of light, airship 10 may produce electrical energy even when sunlight 40 and albedo radiation 50 are scarce.

Based upon the foregoing, the advantages of the present invention are readily apparent. For one, the present invention may be successfully used on several platforms, including for example, lighter-than-air systems (including tethered aerostat systems), heavier-than-air systems, and hybrid systems. Also, the present invention permits a user to engineer the combination of a solar array with an Earth array in an optimal arrangement depending on anticipated operational conditions such as flight latitude and season. The present invention may use conventional solar cells (photovoltaic cells), or may use solar cells specifically tailored for either the solar array or the Earth array.

The present invention may also improve the total weight and weight distribution of the airship. By having an Earth array and a solar array that is smaller than prior art designs, more of the weight of the airship will be distributed along its bottom, resulting in a more stable airship. In the case where the solar array is eliminated, the electrical cable running between the solar array and the power distribution controller is also eliminated, resulting in a further decrease in total weight. These weight reductions may enable greater payload weights and may also enable a reduction in airship size and cost. Also, a greater weight distribution near the bottom of the airship enables significantly greater flexibility for placing payloads on the top of the airship for certain applications.

Reducing or eliminating the solar array may mitigate the deleterious impact of daytime heating of the lifting gas since solar radiation impinging the sun-facing hull surface of the airship may be reflected by hull fabric coatings and optical treatments instead of being absorbed by solar cells with a portion of the energy being converted into thermal energy.

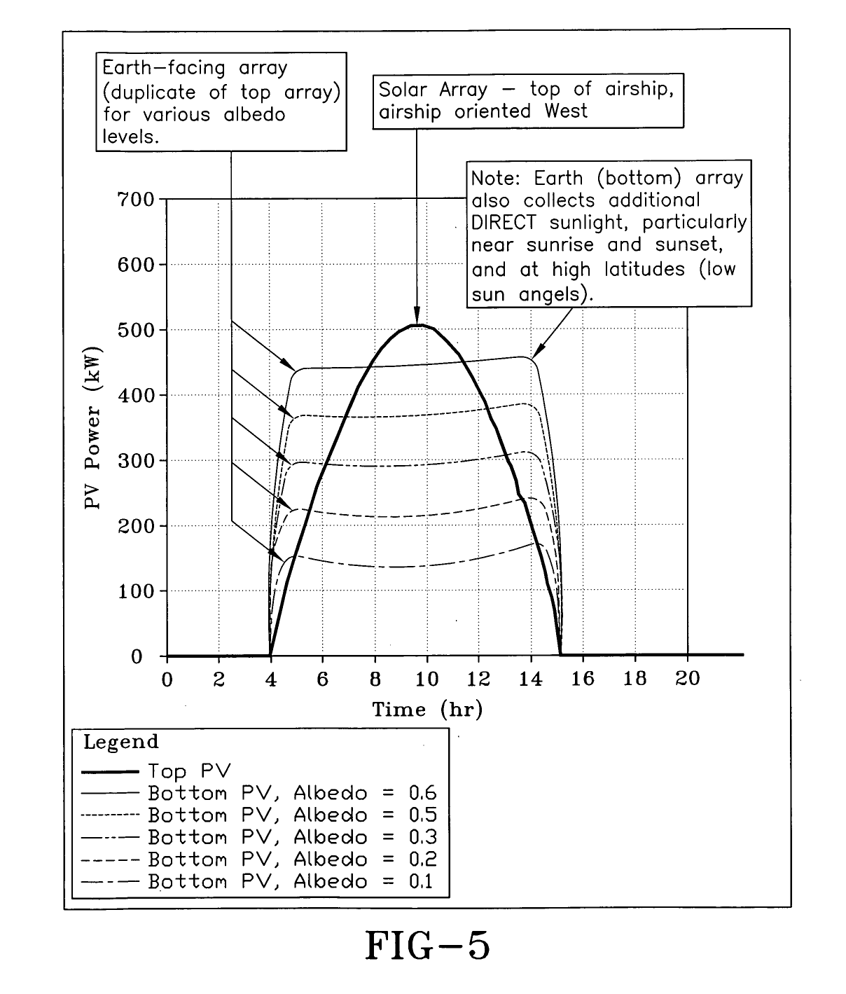

The present invention will also reduce the diurnal variability of electrical energy generated. Turning now to FIG. 5, it can be seen that a conventional solar array displays significant variation in power generation during the day. In contrast, the Earth array displays relatively constant power generation during the day, with localized maxima corresponding to direct solar radiation impinging the Earth array at sunrise and sunset. As the sun rises or sets, the sun is at low sun angles and the Earth array can collect direct solar radiation.

The present invention also has the benefit of using the Earth array to collect solar radiation. During very low sun angles, such as during sunrise or sunset, and during winter at high latitudes, the sun directly illuminates the bottom portion of the airship. The ability to gather direct solar radiation at low sun angles is a significant benefit for operation at high latitudes during winter. Thus, the present invention may reduce energy dependency on latitude. And because the Earth array is less sensitive to individual solar cell normal angles than the solar array, other airship elements (such as RF antenna components) may be interspersed with the solar cells of the Earth array without critically affecting electrical energy production capability.

Also, because stratospheric airships are designed to point into the wind, portions of the solar array are often shadowed. However, the wind direction will have relatively little impact on the electrical energy generated by the Earth array.

Thus, it can be seen that the objects of the invention have been satisfied by the structure and its method for use presented above. While in accordance with the Patent Statutes, only the best mode and preferred embodiment has been presented and described in detail, it is to be understood that the invention is not limited thereto or thereby. Accordingly, for an appreciation of the true scope and breadth of the invention, reference should be made to the following claims.

What is claimed is:

1. An airship and power generation system comprising:
a hull having a top portion and a bottom portion;
a solar array carried by said top portion;
an Earth array carried by said bottom portion;
wherein said solar array converts solar radiation into electrical energy and said Earth array converts albedo radiation into electrical energy; and
a power distribution controller which receives electrical energy from said solar array and said Earth Array.

2. The power generation system of claim 1, further comprising:
a power storage device, whereby said power distribution controller selectively transfers said electrical energy to said power storage device, and whereby said power distribution controller selectively transfers said electrical energy from said power storage device to the airship's electrical components.

3. The power generation system of claim 1, wherein said solar array and said Earth array are comprised of solar cells.

4. The power generation system of claim 3, wherein said solar cells convert electromagnetic radiation having wavelengths of about 0.2 to about 3.0 microns into electrical energy by the photovoltaic effect.

5. The power generation system of claim 1, wherein said solar array and said Earth array are comprised of similar solar cells.

6. The power generation system of claim 1, wherein said solar array and said Earth array are comprised of different solar cells.

7. The power generation system of claim 6, wherein said solar array is comprised of solar cells that are specifically tuned for the spectrum of direct solar radiation, and wherein said Earth array is comprised of solar cells that are specifically tuned for the spectrum of albedo radiation.

8. The power generation system of claim 1, wherein said solar array covers less surface area of said airship than said Earth array.

9. A method for powering an airship comprising:
providing an airship having electronic devices and a hull with a top portion and a bottom portion;
providing an Earth array on said bottom portion;
connecting a power distribution controller to said Earth array electronic devices;
connecting a power storage device to said power distribution controller;
converting incident radiation impinging on said Earth array into electrical energy;
receiving said electrical energy in said power distribution controller; and
transferring electrical energy between said power distribution controller, said power storage device, and said electronic devices.

10. The method of claim 9 further comprising:
directing a man-made source of radiation at said airship.

11. The method of claim 9, further comprising converting incident radiation impinging on said Earth array into electrical energy by the photovoltaic effect.

12. The method of claim 9 further comprising:
providing a solar array on said top portion; and
connecting said solar array to said power distribution controller.
